(19) United States
(12) Patent Application Publication
(10) Pub. No.: US 2008/0232176 A1
(43) Pub. Date: Sep. 25, 2008

(54) Portable Information Terminal

(76) Inventors: Toyokazu OTA, Tokyo (JP); Yasumasa Nakatsugawa, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/046,288

(22) Filed: Mar. 11, 2008

(30) Foreign Application Priority Data
Mar. 23, 2007 (JP) P2007-077878

(51) Int. Cl. G11C 7/10

(52) U.S. Cl. 365/189.14

(57) ABSTRACT

The present invention provides a portable information terminal having installed therein an IC chip. The portable information terminal includes an internal memory disposed within the IC chip driven by using power supplied via a reader/writer, which is impossible to be accessed from outside the IC chip, an external memory driven by using power from an external power source installed outside the IC chip and a data management unit that controls data write processing or data read processing executed to write data into or read data from the internal memory or the external memory in correspondence to the power supply state pertaining to the external memory. The data management unit selects data with a high access frequency or a high priority among a plurality of sets of data recorded in the external memory and records the selected data into the internal memory.

### CROSS REFERENCES TO RELATED APPLICATIONS

The present invention contains subject matter related to Japanese Patent Application JP 2007-077878 filed in the Japan Patent Office Mar. 23, 2007, the entire contents of which are incorporated herein by reference.

### BACKGROUND OF THE INVENTION

1. Field of the Invention

The present invention relates to a portable information terminal.

2. Description of the Related Art

In recent years, a wide variety of services have come to be offered by using non-contact IC (integrated circuit) chips which are now utilized in diverse modes of application. For instance, services are offered and products are sold/purchased by using non-contact IC chips at entrances to the boarding areas in transit systems, various types of retail shops, automatic vending machines and the like. In addition, noncontact IC chips are carried by users in diverse forms. While a noncontact IC chip has been typically used in the form of a card such as a credit card or a debit card, noncontact IC chips are also widely used in portable information terminals such as portable telephones today, as disclosed in JP2005-174088A. Such portable information terminals include PDA (personal digital assistant) units, personal computers and portable game machines as well as portable telephones. As the performance level of noncontact IC chips has improved in recent years, more advanced services have become available. This has resulted in a significant increase in the volume of data that is recorded into a noncontact IC chip, giving rise to a concern that increases in both the size and the cost of noncontact IC chips may be inevitable.

### SUMMARY OF THE INVENTION

While highly advanced services may be provided through the use of a noncontact IC chip having a large capacity memory installed therein, the size and cost of such a chip will be considerable. Accordingly, the applicant of the present invention proposed a technology that allows a required volume of data to be held without having to increase the size of the noncontact IC chip by storing the data that would normally be stored in the noncontact IC chip into a large capacity memory in the portable information terminal instead. By adopting this technology, the cost of the noncontact IC chip may be reduced and the range of noncontact IC chip applications may be expanded.

However, the large capacity memory at the portable information terminal is available for use when the power to the portable information terminal is in an ON state. In addition, the access speed at the large capacity memory is low compared to the access speed at the internal memory in the noncontact IC chip. There is an added concern that the security of the data recorded into the large capacity memory in the portable information terminal is not fully assured.

Accordingly, the present invention having been completed by addressing the issues discussed above provides a new and improved portable information terminal that enables efficient data management through the use of a memory installed outside the noncontact IC chip.

According to an embodiment of the present invention, there is provided a portable information terminal having installed therein and IC chip capable of data read or data write via a reader/writer.

The portable information terminal includes an internal memory formed within the IC chip driven by using power supplied via the reader/writer, which is impossible to be accessed from outside the IC chip, an external memory driven by using power from an external power source installed outside the IC chip and a data management unit that controls data write processing or data read processing executed to write data into or read data from the internal memory or the external memory in correspondence to the power supply state pertaining to the external memory. The data management unit selects data with a high access frequency or a high priority among a plurality of sets of data recorded in the external memory and records the selected data into the internal memory.

Even when the power source of the portable information terminal is in an OFF state, a function of the IC chip can be utilized by using the data recorded in the internal memory. In addition, since the data with high access frequency or high priority are cached in the internal memory, the data can be accessed with improved speed.

The data management unit may adopt a structure that allows it to store data received from the reader/writer into the internal memory, and then write the received data into the external memory after confirming that power is being supplied to the external memory. With the data management unit adopting such a structure, a function of the IC chip can be utilized by using the data recorded in the internal memory even when no power is supplied to the portable information terminal.

Alternatively, the data management unit may adopt a structure that allows it to access the external memory after receiving a read command pertaining to a set of data from the reader/writer only if the set of data is not present in the internal memory. In this case, the data read is executed by giving priority to data in the relatively fast internal memory, and thus, the data read processing can be executed at higher speed.

The IC chip may further include an encryption processing unit that encrypts data written into the external memory and decrypts data read out from the external memory. An encryption key to be used to encrypt or decrypt data may be held in the internal memory. In such a case, the encryption processing unit may encrypt or decrypt data by using the encryption key. Since data to be recorded into the low security external memory are encrypted, the data recorded in the external memory are protected with a higher level of security.

The external memory may include at least one management data area where data are recorded by the data management unit and a management ID that is updated every time the data are recorded. The data management unit, operating in conjunction with such an external memory, may record into the internal memory the updated management ID every time data are recorded in the management data area and detect an error in the external memory by comparing the management ID in the management data area with the management ID recorded in the internal memory. Since these measures ensure that an error is detected whenever a physical failure occurs in the external memory or a data destruction occurs in the external memory, data can be managed with better safety.

Alternatively, the external memory may include a plurality of management data areas each having recorded therein data recorded by the data management and a management ID that is updated every time the data are recorded. The data management unit, operating in conjunction with such an external memory, may record into the internal memory the updated management ID every time data are recorded into a given management data area, compare management IDs recorded in the individual management data areas with the management ID in the internal memory and read desired data from a management data area with a matching management ID or write data into a management data area with a management ID that does not match the management ID in the internal memory since a greater extent of redundancy is assured with regard to the recording areas in the external memory, better safety is assured for data against data loss if the power source becomes disconnected while data are being written or read and data recovery is enabled by using the old data.

According to the embodiment of the present invention described above, efficient data read/write control is enabled through the use of a memory installed outside a noncontact IC chip.

### BRIEF DESCRIPTION OF THE DRAWINGS

FIG. 1 illustrates the functional structure adopted in the portable information terminal achieved in an embodiment of the present invention;

FIG. 2 shows the structure of the access log used in the embodiment;

FIG. 3 presents a flowchart of the startup processing executed in the portable information terminal in the embodiment;

FIG. 4 presents a flowchart of the management ID classification processing executed in the portable information terminal in the embodiment;

FIG. 5 presents a flowchart of the data read processing executed in the portable information terminal in the embodiment; and

FIG. 6 presents a flowchart of the data write processing executed in the portable information terminal in the embodiment.

### DETAILED DESCRIPTION OF THE PREFERRED EMBODIMENTS

Hereafter, a preferred embodiment of the present invention will be described in detail with reference to the appended drawings. Note that in this specification and the appended drawings, structural elements that have substantially the same functions and structures are denoted with the same reference numerals and repeated explanation of these structural elements is omitted.

### Embodiment of the Present Invention

Before the functional structure adopted in the portable information terminal in an embodiment of the present invention is described in detail, the embodiment is briefly outlined.

### Outline of the Embodiment

A data management technology that enables safe and high speed read/write of data by using a secure memory (hereafter referred to as an internal memory) within an IC chip installed in a portable information terminal and a non-secure memory (hereafter referred to as an external memory) installed outside the IC chip is implemented in the embodiment. The term “secure memory” as used in this context refers to a memory that does not allow data recorded therein to be accessed from outside the IC chip.

The data management technology described above is implemented in the IC chip in the embodiment by first encrypting data to be recorded into the external memory with an encryption key or the like stored in the internal memory and then storing the data having been encrypted (hereafter referred to as encrypted data) into the external memory. When encrypted data stored in the external memory are used, the IC chip decrypts the encrypted data stored in the external memory by using the encryption key or the like held in the internal memory. By encrypting data stored in the non-secure external memory as described above, robust protection against illegal access from the outside of the portable information terminal is assured to enable safe data management.

In addition, a data management technology whereby data identification information is held in both the internal memory and the external memory is adopted in the embodiment so as to detect any data overwrite in the external memory or any tampering with data in the external memory. Since any illegal access from outside the portable information terminal is detected with ease in this manner, better safety is assured in data management.

Power may be supplied to the IC chip and the external memory via different power supply systems. For instance, the IC chip may receive a carrier wave originating from a reader/writer and be driven by power induced from the carrier wave. In this case, the power will be also supplied to the internal memory installed in the IC chip. Power may be supplied from a power source disposed at the portable information terminal to the external memory. This means that when the power source at the portable information terminal is in the OFF state, the IC chip is not able to read out data recorded in the external memory or write data into the external memory. However, the user will naturally wish to be able to use the IC chip whether the power source at the portable information terminal is in the ON state or in the OFF state. In other words, there is a need for a technology that enables optimal management of the data in the external memory in correspondence to the power supply state.

Accordingly, the data management technology achieved in the embodiment provides a method for managing data in an optimal manner in correspondence to the power supply state pertaining to the power supply to the external memory when executing data read/write processing.

For instance, the IC chip in the embodiment caches data which are used with high frequency into the internal memory and selects the cached data or data in the external memory for use in correspondence to the power supply state pertaining to the power supply to the extra memory. The IC chip having such a selection function can be driven by using the data cached in the internal memory even when power is not supplied to the external memory. In addition, since the internal memory that can be accessed at relatively high speed is used as a cache, higher-speed memory access is enabled.

As described above, the embodiment relates to a data management technology for safer data management enabled through the use of a secure internal memory and a nonsecure external memory. An IC card adopting this data management technology is able to utilize the external memory with a relatively large capacity installed at the portable information terminal with a high level of safety. The following is an explanation of a functional structure that may be adopted in the portable information terminal in which the data management technology is embodied.

(Functional Structure of Portable Information Terminal 100)

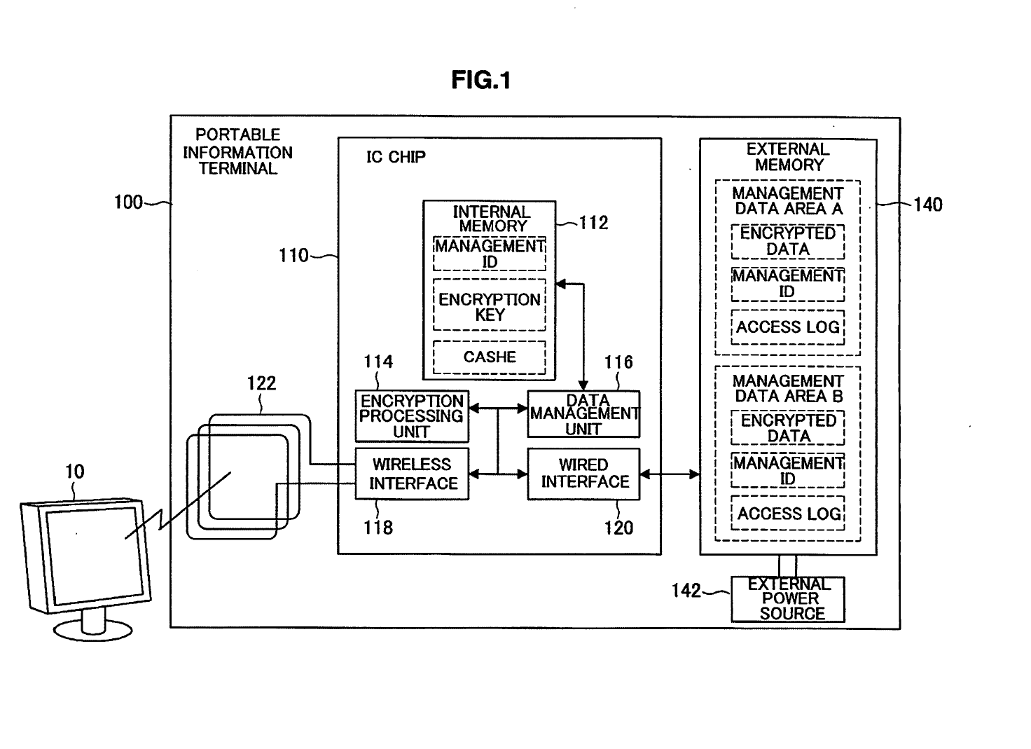

A portable information terminal 100 shown in FIG. 1 includes, as its primary components, an IC chip 110, an external memory 140 and an external power source 142. The portable information terminal 100 is capable of exchanging data with a reader/writer 10 provided as an external unit. The IC chip 110 in the portable information terminal 100 is driven on the power supplied via an electromagnetic wave transmitted from the reader/writer 10. The external memory 140, on the other hand, is driven on the power supplied from the external power source 142. The external power source 142 supplies power to be used to drive various components (not shown) in the portable information terminal 100 other than the IC chip 110. In other words, the IC chip 110 receives power provided by the reader/writer 10, whereas the external memory 140 receives power supplied from the external power source 142. It is assumed that the IC chip 110 is capable of writing data into or reading data from the external memory 140 and also of managing data in the external memory 140.

(Functional Structure of IC Chip 110)

In reference to FIG. 1, the functional structure of the IC chip 110 is described in further detail. The IC chip 110 includes, as its primary components, an internal memory 112, an encryption processing unit 114, a data management unit 116, a wireless interface 118, a wired interface 120 and an antenna 122. It is to be noted that although not shown, the IC chip 110 may include a computation device such as a CPU (central processing unit), a storage device having recorded therein a program that enables the computation device to fulfill various functions and the like. The IC chip 110 assumes a structure that makes access from the outside impossible.

(Internal Memory 112)

A management ID used to track the update status of data recorded in the external memory 140, an encryption key used to encrypt data to be recorded in the external memory 140 and cache data with a high access frequency or a high priority are mainly recorded in the internal memory 112. The internal memory 112 assures a higher response speed compared to the external memory 140. As data with, for instance, high access frequency or high priority among the data recorded in the external memory 140 are cached in the internal memory 112, the overall memory access is improved.

It will be obvious that the internal memory may be designed so that data that require faster memory access are stored into the internal memory 112 with priority. In addition, the internal memory 112 is designed so as to disallow access from an external device present outside the IC chip 110. Such an internal memory 112 is a tamperproof memory. In addition, while the data recorded into the internal memory 112 are referred to as cache data, as described above, data may be permanently held in the internal memory 112 instead.

(Encryption Processing Unit 114)

The encryption processing unit 114 encrypts data to be recorded into the external memory 140 and decrypts data recorded in the external memory 140 by using the encryption key recorded in the internal memory 112. In the following description, data having been encrypted may be referred to as encrypted data. The encryption processing unit 114 uses the encryption key recorded in the internal memory 112 to encrypt or decrypt data. The encryption processing unit 114 may encrypt or decrypt data by adopting a specific encryption method such as the DES (data encryption standard), the triple-DES or the AES (advanced encryption standard). DES is the most commonly adopted standard in common key encryption. The triple-DES is a method whereby the encryption processing executed in conformance to the regular DES is repeated three times. The AES is the next generation standard encryption method sponsored by the US government, which has been in development in the US by the National Institute of Standards and Technology (NIST).

(Data Management Unit 116)

The data management unit 116 controls the operations of the various components disposed within the IC chip 110 and also executes data write/read processing to write data into or read data from the external memory 140. It is to be noted that the data management unit 116 executes data read/write processing for reading data from or writing data into the external memory 140 as well as controlling the various components within the IC chip 110. During the data read/write processing, the data control unit 116 controls the encryption processing unit 114 to encrypt or decrypt data. It is to be noted that the data management unit 116 may be constituted with a computation device such as a CPU and may be designed so as to fulfill various functions in conformance to a program installed in the internal memory 112 or another storage device (not shown).

(Wireless Interface 118)

The wireless interface 118 may be constituted with, for instance, a front-end circuit (not shown), a power source reproduction circuit (not shown) and the like. These components input power and data obtained from the reader/writer 10 via a carrier wave to the IC chip 110. The front-end circuit receives the carrier wave originating from the reader/writer 10 through the antenna 122 and reproduces a clock and data to be used to drive the IC chip 110 by dividing the frequency of the carrier wave. The power source reproduction circuit reproduces power to be used to drive the IC chip 110 from the carrier wave. The data received from the reader/writer 10 are input via the wireless interface 118 to the data management unit 116. In addition, data input from the data management unit 116 through the antenna 122 are transmitted to the reader/writer 10 via the wireless interface 118.

(Wired Interface 120)

Data input from the data management unit 118 are written into the external memory 140 or data are read from the external memory 140 via the wired interface 120 under control executed by, for instance, the data management unit 116. The data input from the data management unit 116 to the wired interface 120 are data having been encrypted by the encryption processing unit 114.

(Antenna 122)

The antenna 122 assuming the form of, for instance, a loop antenna, obtains a transmission signal by receiving the carrier wave originating from the reader/writer 10 and also generates an electromotive force induced by using the wireless carrier wave. The induced electromotive force is used as a power source for driving the various components of the IC chip 110. Thus, power is supplied at all times to the internal memory 112 in the IC chip 110 during a data write or a data read. In addition, a transmission signal input from the wireless interface 118 can be transmitted on a carrier wave to the reader/writer 10 through the antenna 122.

(Structure of External Memory 140)

The external memory 140 is constituted with a plurality of management data areas. The external memory in the example presented in FIG. 1 includes a management data area A and a management data area B. In each management data area, encrypted data having been encrypted by the encryption processing unit 114, a management ID used to determine the update status of the encrypted data and an access log carrying history information on the history of encrypted data write/read processing having been executed in correspondence to the management data area are recorded.

The management ID and the access log may be encrypted by the encryption processing unit 114. In addition, the external memory 140 may be a semiconductor memory such as an EEPROM (electrically erasable and programmable read-only memory) a flash memory or an FeRAM (ferroelectric random access memory), a magnetic recording medium such as a hard disk drive, an optical recording medium or a magneto-optical recording medium. Also, the external memory 140 may be a removable recording medium that can be detached from the portable information terminal 100.

(Generational Management Executed for Management Data Areas Based Upon Management IDs)

The role of the management IDs is now explained. A management ID is an identifier used for the update status of data recorded in a given management data area among the plurality of management data areas in the external memory 140. For instance, a value obtained by adding a predetermined value (e.g., 1) to the management ID in the management data area where the most up-to-date data are recorded is set for the management ID corresponding to the management data area where the data become updated. Accordingly, by referencing the values indicated by the management IDs, the management data area having the latest data recorded therein can be identified.

As a example, the situation illustrated in FIG. 1, in which the external memory includes two management data areas A and B with encrypted data, a management ID and an access log stored in each of the management data areas, is examined. Under these circumstances, when recording encrypted data into the external memory 140, the data management unit 116 references the management IDs in the individual management data areas. Then, the data management unit 116 recognizes the management data area with the management ID thereof indicating a greater value as the management data area holding newer data recorded therein and, accordingly, records the encrypted data into the other management data area where older data are recorded. During this process, the data management unit 116 sets a new management ID for the management ID corresponding to the management data area where the new encrypted data have been stored. A value obtained by, for instance, adding a predetermined value (e.g., 1) to the value indicated by the management ID for the management data area where the most recent data have been stored prior to the data update is set for the new management ID.

By executing generational management based upon the management IDs for the plurality of management data areas as described above, recovery processing can be executed with the old data copied from the other management data area even in the event of trouble such as a power error occurring while, for instance, data are being written into a given management data area.

(Access Log Structure and Data Priority Level)

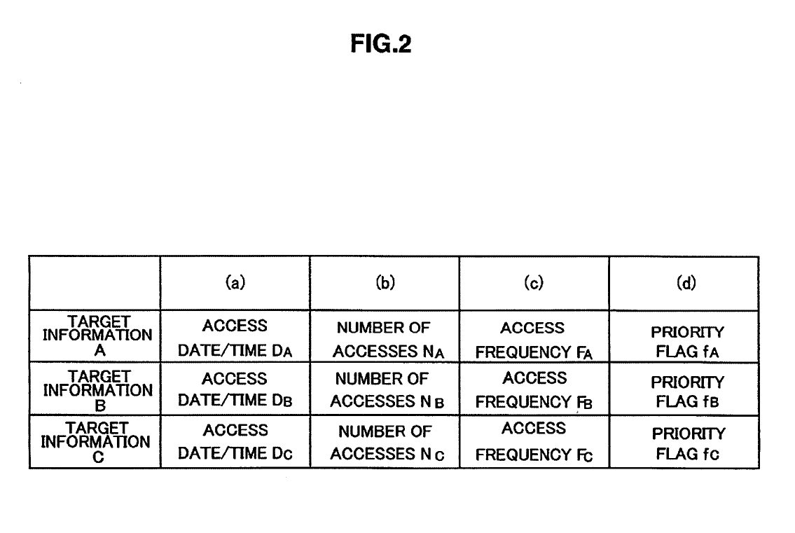

Now, in reference to FIG. 2, the structure adopted in the access logs is briefly explained. The access logs each hold history information to be used when, for instance, selecting priority data to be cached into the internal memory 112 with priority among a plurality of sets of data recorded in the corresponding management data area. In the following explanation, the priority levels of data recorded in the external memory 140 are also described. FIG. 2 shows an example of a structure that may be adopted in the access logs in the embodiment.

As shown in FIG. 2, an access log contains information indicating the access date/time, the number of accesses, the access frequency, a priority flag (or a priority ranking) and the like in correspondence to each set of target information (encrypted data). The data management unit 116 first references the priority flags (data item (d)) corresponding to the individual sets of target information and designates target information with a priority flag thereof in a valid state as candidate data that may be cached. It is to be noted that the data management unit 116 may sustain the priority flag for specific data in the valid state at all times. For instance, in order to hold data requiring fast access in the internal memory 112 at all times, the data management unit 116 may set the priority flag for the data in the valid state at all times.

The data management unit 116 determines the priority level of each set of information based upon the contents of a data item selected by the user from, for instance, data items (a)˜(c) shown in FIG. 2. Namely, the data management unit 116 may reference a preselected data item among the data items (a)˜(c) in FIG. 2 when determining the priority levels. For instance, if the data item (a) is selected, the data management unit 116 gives first priority to data with the most recent access date/time among the candidates. If, on the other hand, the data item (b) is selected, the data management unit 116 gives first priority to the data with the greatest number of accesses among the candidates. If the data item (c) is selected, the data management unit 116 gives priority to data with the highest access frequency among the candidates.

As described above, the data management unit 116 is able to select high priority data from the plurality of sets of target information. It is to be noted that the access date/time indicated in the data item (a) in correspondence to each set of target information is updated to indicate the most recent access date/time whenever the corresponding target information is accessed. In addition, the number of accesses indicated in the data item (b) in correspondence to each set of target information is updated so as to indicate a value obtained by adding 1 to the ongoing number of accesses whenever the corresponding target information is accessed. Furthermore, the access frequency indicated in the data item (c) in correspondence to each set of target information is updated to indicate the most recent access frequency value calculated based upon the value indicated in the data item (a) and the corresponding time point. The data management unit 116 may calculate the access time interval (equivalent to the number of accesses made over a most recent time unit) based upon the difference between the date/time at which the information was accessed previously and the date/time of the current access. The update processing described above may be executed by, for instance, the data management unit 116.

As described above, the data management unit 116 manages the priority levels of the data stored in the various management data areas in the external memory at 140. When caching data in a management data area into the internal memory 112, the data management unit 116 is able to read out high priority data and record the high priority data thus read out into the internal memory 112 in conformance to a specific rule adopted to recognize the priority levels such as any of those described above.

The portable information terminal 100 in the embodiment, the functional structure of which has been explained above, has different power supply sources for the IC chip 110 and the external memory 140. The portable information terminal 100 also includes a structural element that encrypts data to be recorded in to the external memory 140. The portable information terminal 100 further includes a structural element that caches data into the internal memory 112. The following is a detailed explanation of a data management method through which data are written into or read out from the external memory 140.

### Data Management Method Achieved in the Embodiment

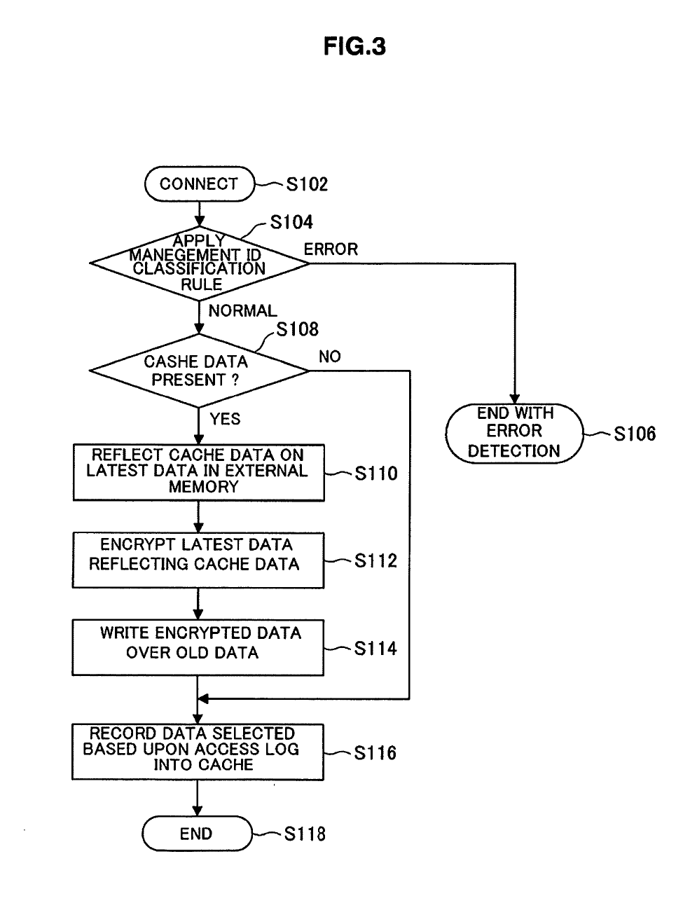

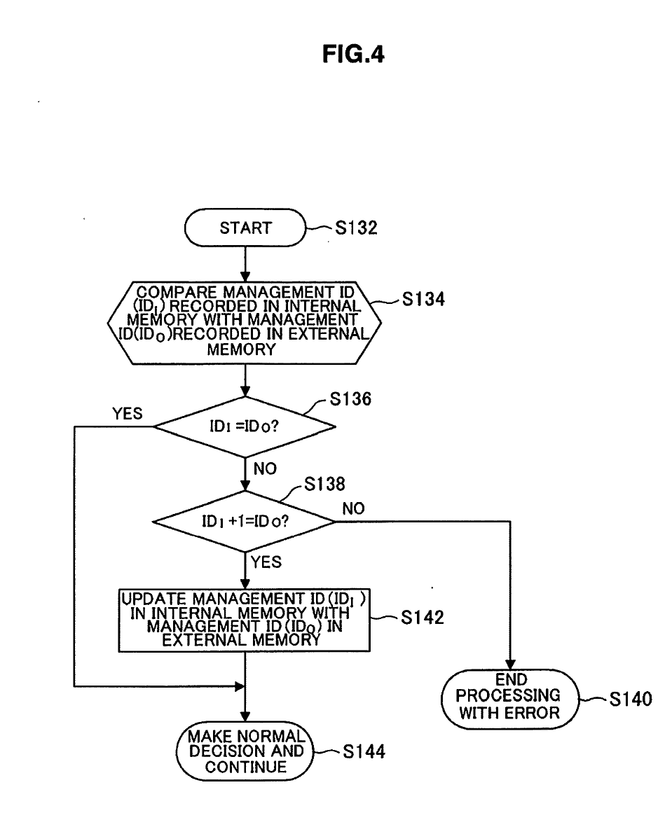

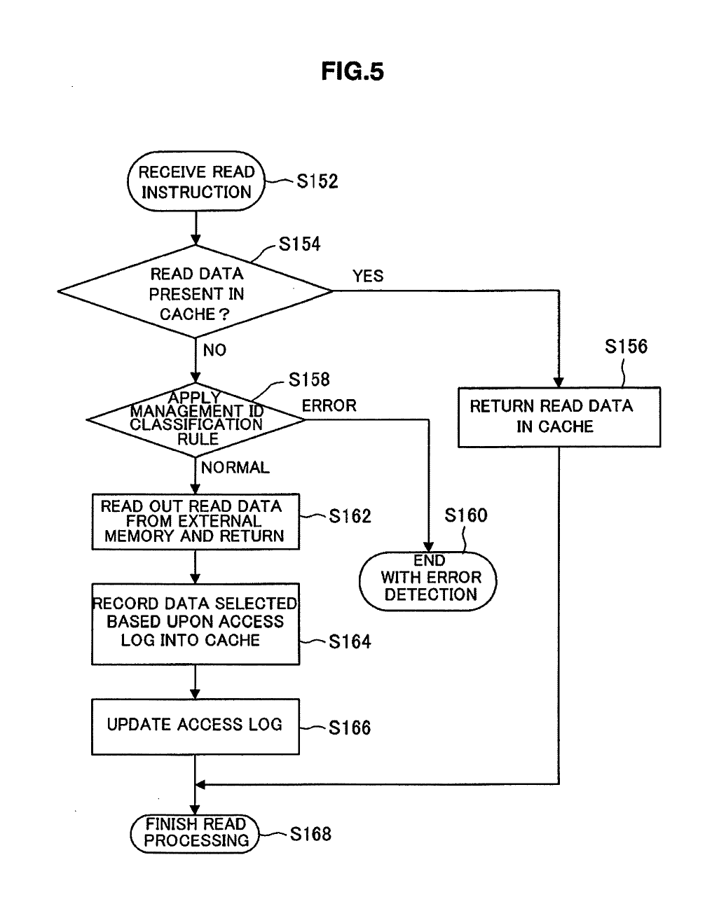

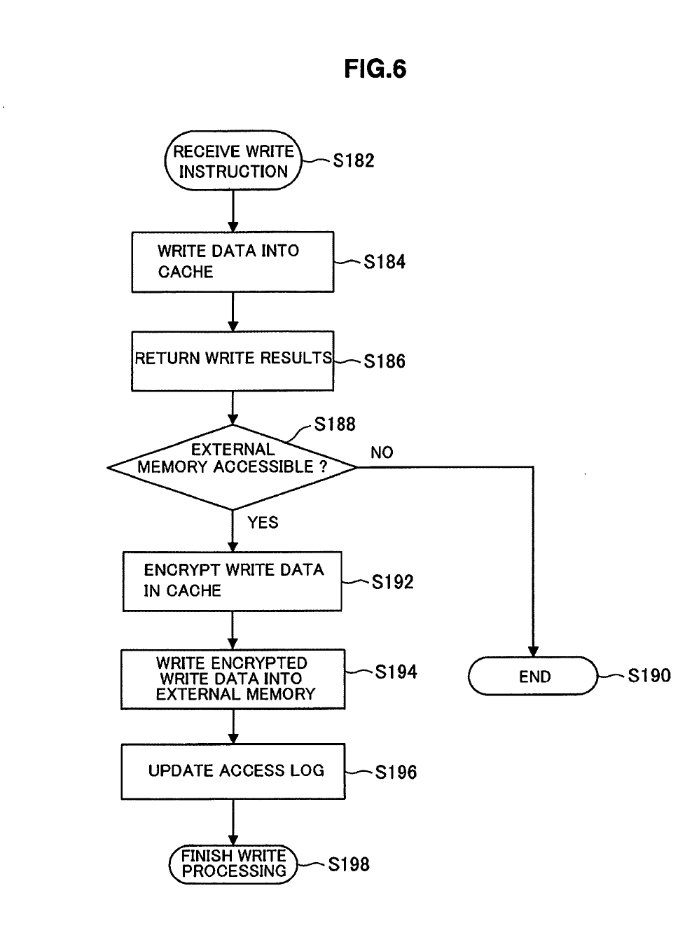

In reference to FIGS. 3 through 6, the data management method achieved in the embodiment is explained. FIG. 3 presents a flowchart of the data management executed as the portable information terminal 100 is started up. FIG. 4 presents a flowchart of the error detection processing executed for the external memory 140 by using the management IDs. FIG. 5 presents a flowchart of the data read processing executed by the reader/writer 10 to read data from the portable information terminal 100. FIG. 6 presents a flowchart of the data write processing executed by the reader/writer 10 to write data at the portable information terminal 100.

(Data Management at Startup of the Portable Information Terminal 100)

First, in reference to FIG. 3, the data management executed as the portable information terminal 100 is started up is described.

As power is supplied to the external memory 140 with the power source of the portable information terminal 100 entering the ON state or the external memory 140 becoming connected to the portable information terminal 100, the IC chip 110 becomes connected to the external memory 140 (S102). Next, the data management unit 116 references the management IDs recorded in the various management data areas in the external memory 140 and the management ID recorded in the internal memory 112 and applies the management ID classification rule (S104). This management ID classification rule is used to determine whether or not data recorded in the external memory are old data. Based upon this rule, an “error” decision is made if the data in the external memory are old but a “normal” decision is made otherwise.

If an error decision is made based upon the management ID classification rule, the data management unit 116 terminates the connection with the external memory 140 due to error detection (S106). If, on the other hand, a “normal” decision is made based upon the management ID classification rule, the data management unit 116 makes a decision as to whether or not there are any cache data present in the internal memory 112 (S108). If it is decided that there are no cache data in the internal memory 112, the data management unit 116 references the access logs recorded in the various management data areas in the external memory 140 and records the high priority data into the internal memory 112 as cache data (S116).

If, on the other hand, it is decided that there are cache data present in the internal memory 112, the data management unit 116 reflects the cache data in the internal memory 112 on the most recent data in the external memory 140 (S110). Namely, the data management unit 116 generates data by reflecting the history information corresponding to the cache data in the internal memory 112 on the most recent data in the external memory 140. At this time, the data management unit 116 reads out the most recent encrypted data by referencing the management IDs recorded in the individual management data areas in the external memory 140. Then, the data management unit 116 first decrypts the most recent encrypted data via the encryption processing unit 114 and then reflects the contents of the cache data in the internal memory 112 on the decrypted data.

Next, the data management unit 116 engages the encryption processing unit 114 to encrypt the latest data reflecting the cache data in the internal memory 112 (S112). Then, the data management unit 116 records the encrypted latest data into the external memory 140 (S114). At this time, the data management unit 116 references the management IDs recorded in the individual management data areas in the external memory 140 and records the latest data into the management data area currently holding the older encrypted data recorded therein.

Next, the data management unit 116 references the access logs recorded in the individual management data areas in the external memory 140 and records high priority data into the internal memory 112 as cache data (S116). Subsequently, the IC chip 110 ends the data management processing executed at the startup of the portable information terminal 100.

As described above, since the data in the external memory 140 are updated at the startup of portable information terminal 100, a satisfactory level of consistency between the data in the internal memory 112 and the data in the external memory 140 is sustained.

(Management ID Classification Processing)

Now, in reference to FIG. 4, the management ID classification rule mentioned earlier is explained.

The classification processing executed based upon the management IDs starts as the data management unit 116 reads out the management IDs recorded in the management data areas in the external memory 140 and the management ID recorded in the internal memory 112 (S132). The data management unit 116 then compares the management ID (ID_{I}) recorded in the internal memory 112 with a management ID (ID_{O}) recorded in the external memory 140 (S134). At this time, the data management unit 116 designates the management ID indicating the greatest value among the management IDs recorded in the individual management data areas in the external memory 140 as ID_{O}.

The data management unit 116 then makes a decision as to whether or not ID_{I}=ID_{O} is true (S136). If ID_{I}=ID_{O}, the data management unit 116 returns a “normal” decision with regard to the data recorded in the external memory at 140 (S144). If, on the other hand, ID_{I}≠ID_{O}, the data management unit 116 makes a decision as to whether or not ID_{I}+1=ID_{O} is true (S138). If ID_{I}+1≠ID_{O}, the data management unit 116 returns an “error” decision for the data recorded in the external memory 140 (S140). If ID_{I}+1=ID_{O}, the data management unit 116 updates the management ID (ID_{I}) in the internal memory with the management ID (ID_{O}) in the external memory (S142). Then, the data management unit 116 returns “normal” for the data recorded in the external memory 140 (S144).

After writing data into the external memory 140, the data management unit 116 updates the management ID in the internal memory 112 with the latest value and thus, the internal memory 112 typically holds the latest management ID. As a result, the data management unit 116, executing the classification processing in conformance to the management ID classification rule described above, is able to detect an error in the external memory 140.

(Data Read Processing)

Next, in reference to FIG. 5, the data read processing executed by the reader/writer 10 to read data from the portable information terminal 100 is explained.

The data management unit 116 first receives a data read command from the reader/writer 10 via the antenna 122 and the wireless interface 118 (S152). The data management unit 116 then makes a decision as to whether or not the data cached in the internal memory 112 include the desired read data (S154). If the desired read data are present in the internal memory 112, the data management unit 116 transmits the desired data cached in the internal memory 112 to the reader/writer 10 (S156) and then finishes the data read processing (S168).

If, on the other hand, the desired read data are not present in the internal memory 112, the data management unit 116 returns either a “normal” decision or an “error” decision with regard to the external memory 140 in conformance to the management ID classification rule explained earlier (S158). If an error is detected in the external memory 140 through the management ID classification processing, the data management unit 116 ends the data read processing (S160). At this time, the data management unit 116 may transmit an error end notification to the reader/writer 10.

If, on the other hand, a “normal” decision is returned with regard to the external memory 140 through the management ID classification processing, the data management unit 116 reads out the desired read data from the external memory 140 and transmits the data thus read out to the reader/writer 10 (S162). At this time, the data management unit 116 references the management IDs in the individual management data areas and obtains the desired read data from the management data area holding the most recent data. Since the data thus obtained are encrypted, the data management unit 116 first engages the encryption processing unit 114 to decrypt the data and then transmits the decrypted data to the reader/writer 10 via the antenna 122 and the wireless interface 118.

Next, the data management unit 116 references the access log in the management data area where the most recent data are stored and records data selected based upon the access log into the internal memory 112 as cache data (S164). At this time, the data management unit 116 first decrypts the data obtained from the management data area in the external memory 140 via the encryption processing unit 114 and then records the decrypted data into the internal memory 112. The data management unit 116 then updates the access log (S166), before finishing the data read processing (S168).

As explained above, upon receiving a data read command from the reader/writer 10 provided as an external unit, the portable information terminal 100 first references the cache data recorded in the internal memory 112 in the IC chip 110. Then, the portable information terminal 100 accesses the external memory 140 only if the cache data do not include the desired read data. If, on the other hand, the cached data do include the desired read data, the portable information terminal 100 uses the data in the internal memory 112 instead of accessing the data recorded in the external memory 140. In this case, since the data are read from the internal memory 112, assuring faster response characteristics then the external memory 140 and high-speed read processing is achieved.

(Data Write Processing)

In reference to FIG. 6, the data write processing executed by the reader/writer 10 to write data into the portable information terminal 100 is explained. The data management unit 116 first receives a data write command and write data from the reader/writer 10 via the antenna 122 and the wireless interface 118 (S182). The data management unit 116 then records the write data having been received into the internal memory 112 as cache data (S184). Subsequently, the data management unit 116 transmits information indicating the write results to the reader/writer 10 via the antenna 122 and the wireless interface 118 (S186). Namely, upon recording the write data into the internal memory 112, the data management unit 116 returns write result information indicating whether or not the write has finished normally to the reader/writer 10.

In addition, the data management unit 116 makes a decision as to whether or not the external memory 140 is accessible (S188). If it is decided that the external memory 140 is impossible to be accessed, the data management unit 116 ends the data write processing (S190). If, on the other hand, it is decided that the external memory 140 is accessible the data management unit 116 engages the encryption processing unit 114 to encrypt the write data having been cached in the internal memory 112 (S192). The data management unit 116 then records the encrypted write data into the external memory 140 (S194). At this time, the data management unit 116 records the encrypted write data into the management data area holding a management ID that does not match the management ID recorded in the internal memory 112.

The data management unit 116 may compare the management IDs recorded in the individual management data areas in the external memory 140 and record the encrypted write data into the management data area holding the management ID indicating a smaller value. In addition, after recording the write data into the external memory 140, the data management unit 116 may erase the write data held in the internal memory 112. Subsequently, the data management unit 116 updates the access log in the management data area into which the write data have been recorded (S196). The data management unit 116 then finishes the data write processing (S198).

As described above, upon receiving a write command and write data from the reader/writer 10, the data management unit 116 first caches the received write data into the internal memory 112 and then makes a decision as to whether or not to continue with the write processing based upon the state of connection with the external memory 140. If the IC chip 110 and the external memory 140 are connected, the data management unit 116 encrypts the cached write data and then records the encrypted data into the external memory 140. Thus, even when the power source (external power source 142) of the portable information terminal 100 is in the OFF state, the write processing can be executed within the IC chip 110 itself. In other words, the data write processing can be executed regardless of the ON/OFF state of the portable information terminal 100. Furthermore, since the data cached in the internal memory 112 are encrypted before they are recorded into the external memory 140, safer data management is assured.

### SUMMARY

As described above, the portable information terminal 100 achieved in the embodiment enables data management that assures both data safety and faster read/write processing. More specifically;

(1) since the high speed internal memory 112 in the IC chip 110 is used as cache memory, data read/write processing can be executed with higher speed,
(2) since data are first encrypted before they are recorded into the external memory 140, better data protection against outside influence is assured,
(3) since the data read/write control is executed in correspondence to the state of power supply to the external memory 140, the data are protected against damage with a higher level of safety. Also, since the external memory 140 is divided into a plurality of management data areas to assure a greater extent of redundancy in data management, better damage proofing is assured for the data.

It will be understood by those skilled in the art that various modifications, combinations, sub combinations and alterations may occur depending upon design requirements and other factors insofar as they are within the scope of the appended claims or the equivalent thereof.

What is claimed is:

1. A portable information terminal having installed therein an IC chip capable of data read or data write via a reader/writer, comprising:
an internal memory disposed within the IC chip driven by using power supplied via the reader/writer, which is impossible to be accessed from outside the IC chip;
an external memory driven by using power from an external power source installed outside the IC chip; and
a data management unit that controls data read/write processing into/from the internal memory or the external memory in correspondence to the power supply state pertaining to the external memory, wherein
the data management unit selects data with a high access frequency or a high priority among a plurality of sets of data recorded in the external memory and records the selected data into the internal memory.

2. A portable information terminal according to claim 1, wherein
the data management unit stores data received from the reader/writer into the internal memory, and then writes the received data into the external memory after confirming that power is being supplied to the external memory.

3. A portable information terminal according to claim 1, wherein
the data management unit accesses the external memory after receiving a read command pertaining to a set of data from the reader/writer only if the set of data is not present in the internal memory.

4. A portable information terminal according to claim 1, wherein
the IC chip further includes an encryption processing unit that encrypts data to be written into the external memory and decrypts data read out from the external memory;
an encryption key to be used to encrypt or decrypt data is held in the internal memory; and
the encryption processing unit encrypts or decrypts data by using the encryption key.

5. A portable information terminal according to claim 1, wherein
the external memory includes at least one management data area where data are recorded by the data management unit and an updated management ID that is recorded every time data are recorded; and
the data management unit records into the internal memory the updated management ID every time data are recorded in the management data area and detects an error in the external memory by comparing the management ID in the management data area with the management ID recorded in the internal memory.

6. A portable information terminal according to claim 1, wherein
the external memory includes a plurality of management data areas each having recorded therein data recorded by the data management and a management ID that is updated every time the data are recorded; and
the data management unit records into the internal memory the updated management ID every time data are recorded into a management data area, compares management IDs recorded in the individual management data areas with the management ID in the internal memory and reads desired data from a management data area with a matching management ID or writes data into a management data area with a management ID that does not match the management ID in the internal memory.
